(19) United States
(12) Patent Application Publication
(10) Pub. No.: US 2019/0074265 A1
(43) Pub. Date: Mar. 7, 2019

(54) SEMICONDUCTOR DEVICE AND MANUFACTURING METHOD OF SEMICONDUCTOR DEVICE

(71) Applicant: Toshiba Memory Corporation, Minato-ku (JP)

(72) Inventor: Keiichi KUSHIDA, Kawasaki (JP)

(73) Assignee: Toshiba Memory Corporation, Minato-ku (JP)

(21) Appl. No.: 15/911,314

(22) Filed: Mar. 5, 2018

(30) Foreign Application Priority Data
Sep. 5, 2017 (JP) 2017-170317

(51) Int. Cl. H01L 25/065; H01L 25/00; H01L 23/00

(52) U.S. Cl. CPC H01L 25/0657; H01L 25/50; H01L 24/73; H01L 24/04; H01L 2224/04042; H01L 2225/0651; H01L 2225/06562; H01L 2225/06513; H01L 2224/73207; H01L 2225/06506

(57) ABSTRACT

According to one embodiment, a semiconductor device includes a first chip and a second chip. The first chip includes a first surface including a first region at an end, the first region in which a first electrode is provided. The second chip includes a second surface including a second region at an end, the second region in which a second electrode is provided. A third region of the first surface of the first chip, other than the first region, and a fourth region of the second surface of the second chip, other than the second region, are bonded in a state that the third region and the fourth region are at least partially opposed to each other, such that the first electrode of the first chip and the second electrode of the second chip are exposed in opposite directions to each other.

### CROSS-REFERENCE TO RELATED APPLICATIONS

This application is based upon and claims the benefit of priority from Japanese Patent Application No. 2017-170317, filed Sep. 5, 2017; the entire contents of which are incorporated herein by reference.

### FIELD

Embodiments described herein relate generally to a semiconductor device and a manufacturing method of a semiconductor device.

### BACKGROUND

Conventionally, there has been discussed a technique of constituting one semiconductor device by stacking a plurality of semiconductor chips. In such a conventional technique, it is desired to provide a semiconductor device (and a manufacturing method of the semiconductor device) with a more advantageous and novel configuration.

### BRIEF DESCRIPTION OF THE DRAWINGS

FIG. 1 is an exemplary and schematic diagram illustrating a configuration of a semiconductor storage device including a memory that is one example of a semiconductor device according to an embodiment;

FIG. 2 is an exemplary and schematic diagram illustrating a planar configuration of a memory chip according to the embodiment;

FIG. 3 is an exemplary and schematic diagram illustrating a cross-sectional configuration of the memory chip according to the embodiment;

FIG. 4 is an exemplary and schematic diagram illustrating a set of memory chips according to the embodiment;

FIG. 5 is an exemplary and schematic diagram illustrating a first configuration example of the semiconductor device according to the embodiment;

FIG. 6 is an exemplary and schematic diagram illustrating a second configuration example of the semiconductor device according to the embodiment;

FIG. 7 is an exemplary and schematic diagram illustrating a third configuration example of the semiconductor device according to the embodiment;

FIG. 8 is an exemplary and schematic diagram illustrating a fourth configuration example of the semiconductor device according to the embodiment; and

FIG. 9 is an exemplary and schematic diagram illustrating a configuration of a semiconductor storage device according to a modification of the embodiment.

### DETAILED DESCRIPTION

In general, according to one embodiment, a semiconductor device includes a first chip and a second chip. The first chip includes a first surface including a first region at an end, the first region in which a first electrode is provided. The second chip includes a second surface including a second region at an end, the second region in which a second electrode is provided. A third region of the first surface of the first chip, other than the first region, and a fourth region of the second surface of the second chip, other than the second region, are bonded in a state that the third region and the fourth region are at least partially opposed to each other, such that the first electrode of the first chip and the second electrode of the second chip are exposed in opposite directions to each other.

Exemplary embodiments of a semiconductor device (and a manufacturing method of the semiconductor device) will be explained below in detail with reference to the accompanying drawings. The present invention is not limited to the following embodiments.

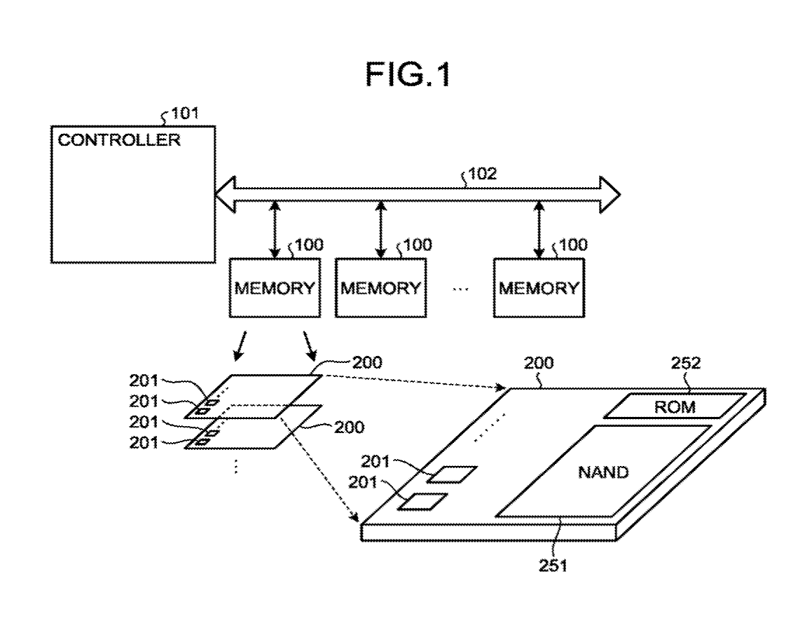

FIG. 1 is an exemplary and schematic diagram illustrating a configuration of a semiconductor storage device including a memory 100 that is one example of a semiconductor device according to an embodiment. This semiconductor storage device can be used as a storage device for a memory card, an SSD, and the like. The technique of the embodiment is also applicable to other general semiconductor devices in addition to the memory 100 used in the semiconductor storage device.

As illustrated in FIG. 1, the semiconductor storage device according to the embodiment includes a plurality of memories 100 and a controller 101 that executes a drive control on the memories 100. The drive control may include, for example, data reading and writing, block selection, error correction, and wear leveling. The controller 101 can transmit a signal to the memories 100 through, for example, a Double Data Rate (DDR) interface.

The memories 100 are connected in parallel to the controller 101 through a channel 102. Each of the memories 100 includes a plurality of memory chips 200. Each of the memory chips 200 includes a plurality of pad electrodes 201. The pad electrodes 201 may be categorized into a pad electrode 201 that receives power supply and a pad electrode 201 that receives data such as a control signal.

Each of the memory chips 200 includes a NAND flash memory 251 and a programmable ROM 252. A unit cell array, a decoder, a sense amplifier, a charge pump circuit, a page buffer, and the like can be provided in the NAND flash memory 251. The programmable ROM 252 can also store therein various types of parameters related to the operation of the memory chip 200.

In FIG. 1, the memory chip 200 including the NAND flash memory 251 is exemplified. However, the technique of the embodiment is also applicable to a memory chip including a memory other than the NAND flash memory 251, such as a dynamic RAM (DRAM) or a resistance RAM (ReRAM).

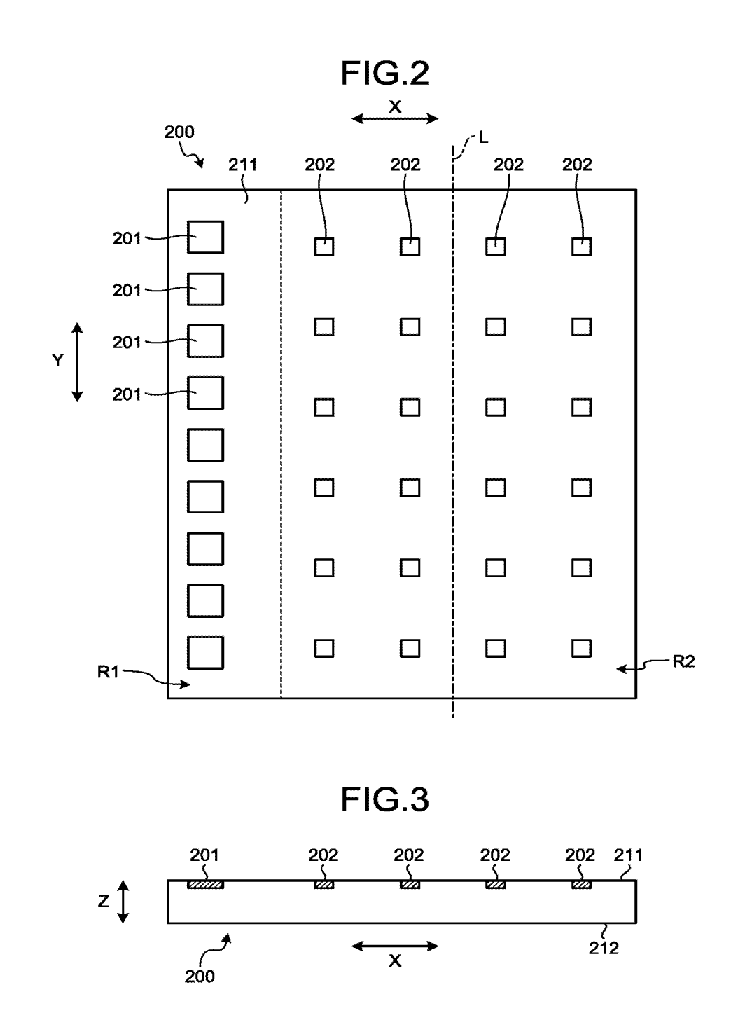

FIG. 2 is an exemplary and schematic diagram illustrating a planar configuration of the memory chip 200 according to the embodiment, and FIG. 3 is an exemplary and schematic diagram illustrating a cross-sectional configuration of the memory chip 200 according to the embodiment.

As illustrated in FIGS. 2 and 3, the memory chip 200 according to the embodiment has a flat cuboid shape. In FIGS. 2 and 3, the arrows (X, Y, and Z) indicating the respective directions are illustrated. The X-direction, the Y-direction, and the Z-direction are perpendicular to each other. The X-direction and the Y-direction extend along the plane on a surface 211 or a back surface 212 of the memory chip 200. The Z-direction extends along the thickness of the memory chip 200.

A region R1 is positioned at the end (edge) portion on one side in the X-direction on the surface 211 of the memory chip 200 (on the left-side longer side in the diagram of FIG. 2). In the region R1, the aforementioned pad electrodes 201 are provided side by side along the Y-direction. On the surface 211 of the memory chip 200, in a region R2 other than the region R1, a plurality of bump electrodes 202 are arrayed in a matrix. The pad electrodes 201 and the bump electrodes 202 are electrically connected through a wire (not illustrated) provided in the memory chip 200.

In the embodiment, the bump electrodes 202 may be categorized into a bump electrode 202 that is an example of a power conductor as a part of the power line, and a bump electrode 202 that is an example of a data conductor as a part of the data bus. Meanwhile, as described above, the pad electrodes 201 may be categorized into a pad electrode 201 that receives power supply and a pad electrode 201 that receives data such as a control signal.

Therefore, in the embodiment, the bump electrode 202 configured as the power conductor and the pad electrode 201 that receives power supply are electrically connected through a wire (not illustrated) in the memory chip 200. Also, the bump electrode 202 configured as the data conductor and the pad electrode 201 that receives data are electrically connected through a wire (not illustrated) in the memory chip 200.

In the embodiment, a pair of memory chips 200 is used, which is described later in detail. More specifically, in the embodiment, the pair of memory chips 200 is bonded (press-fitted) with their respective regions R2 of the surfaces 211 being opposed to each other, such that the pad electrodes 201 of the pair of memory chips 200 are exposed in opposite directions to each other and the bump electrodes 202 of the pair of memory chips 200 are brought into alignment with each other and electrically connected to each other.

Therefore, in the embodiment, in order to secure electrical matching when the pair of memory chips 200 is bonded in the above-described manner, the bump electrodes 202 configured as the power conductor are provided symmetrically with respect to a center line L in the region R2 of the surface 211 of the memory chip 200. Similarly, the bump electrodes 202 configured as the data conductor are provided symmetrically with respect to the center line L.

In the embodiment, the bump electrodes 202 are not limited to being arrayed in a matrix as long as these bump electrodes 202 can be brought into alignment when the pair of memory chips 200 opposed to each other is bonded. In the embodiment, the number of the bump electrodes 202 is not limited to the number exemplified in FIGS. 2 and 3.

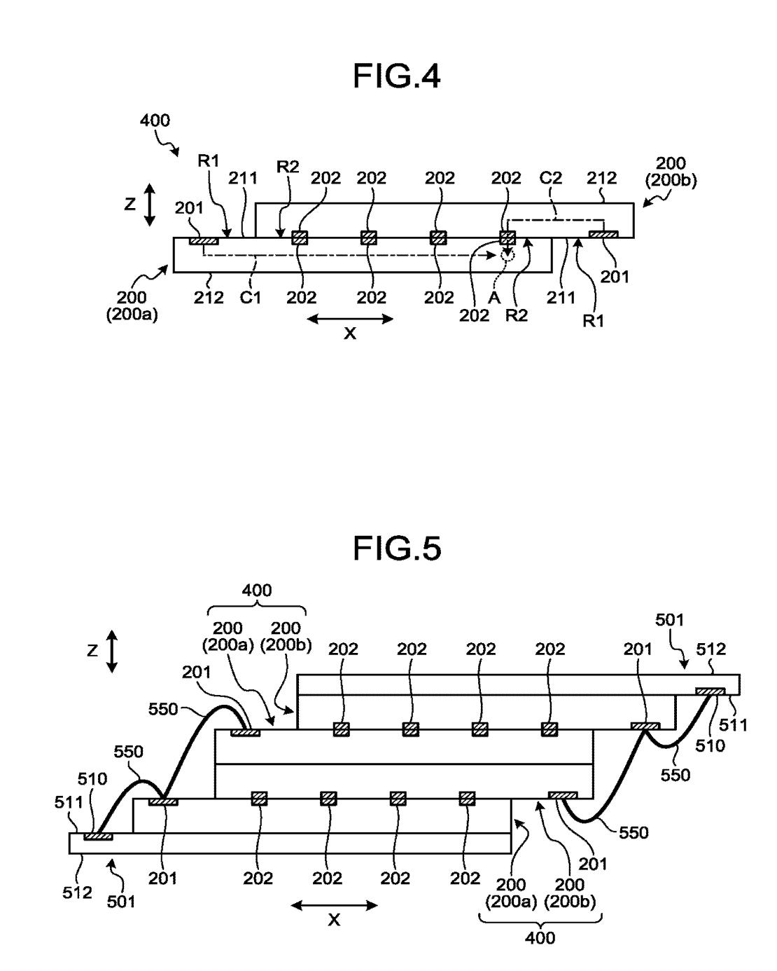

FIG. 4 is an exemplary and schematic diagram illustrating a set 400 of the memory chips 200 according to the embodiment. The set 400 illustrated in FIG. 4 is the most basic unit to be used in each of the following first to fourth configuration examples of the semiconductor device according to the embodiment.

As illustrated in FIG. 4, in the embodiment, a single set 400 is formed of the pair of memory chips 200 bonded to be opposed to each other. In the embodiment, the paired memory chips 200, which form the single set 400, are configured as identical components. However, in the following descriptions, one of the memory chips 200 is sometimes described as “memory chip 200a”, while the other memory chip 200 is described as “memory chip 200b” to be distinguished from each other for convenience of explanation.

In the embodiment, the respective regions R2 of the surfaces 211 of the memory chips 200a and 200b, other than the respective regions R1 where the pad electrodes 201 are each provided, are bonded to be opposed to each other, such that the pad electrode 201 of the memory chip 200a and the pad electrode 201 of the memory chip 200b are exposed in opposite directions to each other. In this configuration, the bump electrodes 202 of the memory chip 200a are aligned with the corresponding bump electrodes 202 of the memory chip 200b. Due to this alignment, the bump electrodes 202 of the memory chip 200a and the corresponding bump electrodes 202 of the memory chip 200b are electrically connected to each other.

In the configuration illustrated in FIG. 4, not only a route C1 via the pad electrode 201 of the memory chip 200a, but also a route C2 via the pad electrode 201 of the memory chip 200b can be used to transmit power (or a control signal) to an area A which is immediately below the bump electrode 202 and is most distanced from the pad electrode 201 in the memory chip 200a, for example. The bump electrode 202 which is most distanced from the pad electrode 201 in the memory chip 200a corresponds to the bump electrode 202 which is nearest from the pad electrode 201 in the memory chip 200b. Thus, the route C2 is shorter than the route C1. Therefore, due to the configuration illustrated in FIG. 4, effects of reducing the wiring resistance and reducing the influence of noise are obtained.

In FIG. 4, the configuration is exemplified in which the respective regions R2 of the memory chips 200a and 200b are entirely bonded in a state that the whole of the bump electrodes 202 are brought into alignment with each other. However, the technique of the embodiment is also applicable to a configuration in which, for example, the respective regions R2 of the memory chips 200a and 200b are at least partially bonded to each other as long as at least one of the bump electrodes 202 of the memory chip 200a is electrically connected to at least one of the bump electrodes 202 of the memory chip 200b.

Several configuration examples of the semiconductor device according to the embodiment are exemplified below, in which a plurality of sets 400 illustrated in FIG. 4 are used.

### First Configuration Example

FIG. 5 is an exemplary and schematic diagram illustrating a first configuration example of the semiconductor device according to the embodiment. In the first configuration example illustrated in FIG. 5, two sets 400 stacked on one another in the Z-direction are interposed between two mounting boards 501, each of which includes a surface 511 and a back surface 512.

In the first configuration example illustrated in FIG. 5, the two sets 400 are stacked in a stepwise manner such that the respective pad electrodes 201 of the memory chips 200a are exposed on one side, while the respective pad electrodes 201 of the memory chips 200b are exposed on the other side. More specifically, in the first configuration example, the upper surface (the back surface 212 illustrated in FIGS. 3 and 4) of the memory chip 200b in the lower set 400 in the diagram of FIG. 5 is bonded to the lower surface (the back surface 212 illustrated in FIGS. 3 and 4) of the memory chip 200a in the upper set 400 in the diagram of FIG. 5.

In addition, in the first configuration example illustrated in FIG. 5, the two sets 400 stacked in a stepwise manner are interposed between the surfaces 511 that are respective mounting surfaces of the two mounting boards 501. That is, in the first configuration example illustrated in FIG. 5, the lower surface (the back surface 212 illustrated in FIGS. 3 and 4) of the memory chip 200a in the lower set 400 in the diagram is mounted on the upper surface (the surface 511) of the lower mounting board 501 in the diagram. Simultaneously, the upper surface (the back surface 212 illustrated in FIGS. 3 and 4) of the memory chip 200b in the upper set 400 in the diagram is mounted on the lower surface (the surface 511) of the upper mounting board 501 in the diagram.

In the first configuration example illustrated in FIG. 5, a pad electrode 510 is provided at the end portion of the surface 511 of the mounting board 501. The pad electrode 510 on the upper surface (the surface 511) of the lower mounting board 501 in the diagram is exposed on the same side as the pad electrodes 201 of the memory chips 200a. The pad electrode 510 on the lower surface (the surface 511) of the upper mounting board 501 in the diagram is exposed on the same side as the pad electrodes 201 of the memory chips 200b.

In the first configuration example illustrated in FIG. 5, the pad electrode 510 and the pad electrodes 201, which are exposed on the same side, are electrically connected to each other by a bonding wire 550. That is, in the first configuration example illustrated in FIG. 5, the pad electrode 510 on the upper surface (the surface 511) of the lower mounting board 501 in the diagram is electrically connected to the pad electrodes 201 of the memory chips 200a. The pad electrode 510 on the lower surface (the surface 511) of the upper mounting board 501 in the diagram is electrically connected to the pad electrodes 201 of the memory chips 200b.

The first configuration example of the semiconductor device illustrated in FIG. 5 is mounted on a package board (not illustrated) including an external terminal for connecting to an external device, and is thereafter sealed with a resin or the like so as to be packaged as a single semiconductor device (for example, the memory 100 exemplified in FIG. 1). On the surface of the package board (not illustrated), an electrode is provided to be connected to the pad electrode 501 on the mounting board 510 through a bonding wire or the like.

In the first configuration example illustrated in FIG. 5, the two sets 400 are interposed between the two mounting boards 501. In the embodiment, it is also allowable that only a single set 400 is interposed between the two mounting boards 501, or three or more sets 400 are stacked on one another between the two mounting boards 501.

### Second Configuration Example

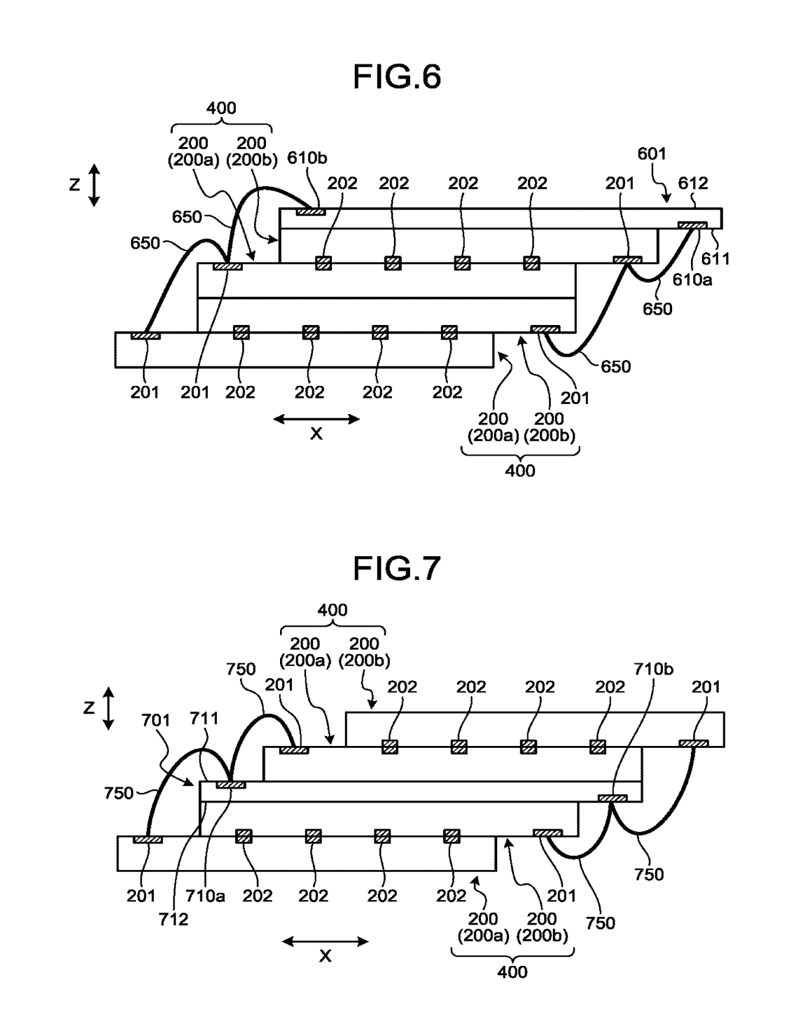

FIG. 6 is an exemplary and schematic diagram illustrating a second configuration example of the semiconductor device according to the embodiment. In the second configuration example illustrated in FIG. 6, the two sets 400 stacked on one another in the Z-direction are mounted on a single mounting board 601 including a surface 611 and a back surface 612.

In the same manner as the first configuration example described above (see FIG. 5), in the second configuration example illustrated in FIG. 6, the two sets 400 are stacked in a stepwise manner such that the respective pad electrodes 201 of the memory chips 200a are exposed on one side, while the respective pad electrodes 201 of the memory chips 200b are exposed on the other side.

However, in the second configuration example illustrated in FIG. 6, the two sets 400 stacked in a stepwise manner are mounted on the surface 611 that is a mounting surface of the single mounting board 601, unlike the first configuration example described above (see FIG. 5). More specifically, in the second configuration example illustrated in FIG. 6, the upper surface (the back surface 212 illustrated in FIGS. 3 and 4) of the memory chip 200b in the upper set 400 in the diagram is mounted on the lower surface (the surface 611) of the mounting board 601.

In the second configuration example illustrated in FIG. 6, a pad electrode 610a is provided at the end portion of the surface 611 of the mounting board 601 on the same side as the pad electrodes 201 of the memory chips 200b. The pad electrode 610a is thus exposed on the same side as the pad electrodes 201 of the memory chips 200b. In the second configuration example illustrated in FIG. 6, a pad electrode 610b is further provided at the end portion of the back surface 612 of the mounting board 601 on the opposite side to the pad electrode 610a, that is, at the end portion of the back surface 612 of the mounting board 601 on the same side as the pad electrodes 201 of the memory chips 200a. The pad electrode 610b is thus exposed on the same side as the pad electrodes 201 of the memory chips 200a.

In the second configuration example illustrated in FIG. 6, the pad electrode 610a and the pad electrodes 201 which are exposed on the same side, that is, the pad electrode 610a on the surface 611 of the mounting board 601 and the pad electrodes 201 of the memory chips 200b are electrically connected by a bonding wire 650. The pad electrode 610b and the pad electrodes 201 which are exposed on the same side, that is, the pad electrode 610b on the back surface 612 of the mounting board 601 and the pad electrodes 201 of the memory chips 200a are electrically connected by the bonding wire 650.

In the same manner as the first configuration example described above, the second configuration example of the semiconductor device illustrated in FIG. 6 is mounted on the surface of a package board (not illustrated) including an external terminal for connecting to an external device, and is thereafter sealed with a resin or the like so as to be packaged as a single semiconductor device (for example, the memory 100 exemplified in FIG. 1). On the surface of the package board (not illustrated), electrodes are provided to be connected respectively to the pad electrodes 610a and 610b on the mounting board 601 through a bonding wire or the like.

In the second configuration example illustrated in FIG. 6, the two sets 400 are mounted on the single mounting board 601. In the embodiment, it is also allowable that only a single set 400 is mounted on the single mounting board 601, or three or more sets 400 are mounted on the single mounting board 601.

### Third Configuration Example

FIG. 7 is an exemplary and schematic diagram illustrating a third configuration example of the semiconductor device according to the embodiment. In the third configuration example illustrated in FIG. 7, a single mounting board 701 including a surface 711 and a back surface 712 is interposed between two sets 400 stacked on one another in the Z-direction.

In the third configuration example illustrated in FIG. 7, the two sets 400 are stacked in a stepwise manner through the mounting board 701 such that the respective pad electrodes 201 of the memory chips 200a are exposed on one side, while the respective pad electrodes 201 of the memory chips 200b are exposed on the other side. More specifically, in the third configuration example illustrated in FIG. 7, the upper surface (the back surface 212 illustrated in FIGS. 3 and 4) of the memory chip 200b in the lower set 400 in the diagram is mounted on the lower surface (the back surface 712) of the mounting board 701. Simultaneously, the lower surface (the back surface 212 illustrated in FIGS. 3 and 4) of the memory chip 200a in the upper set 400 in the diagram is mounted on the upper surface (the surface 711) of the mounting board 701. Therefore, in the third configuration example, the surface 711 and the back surface 712 of the mounting board 701 both serve as a mounting surface.

In the third configuration example illustrated in FIG. 7, a pad electrode 710a is provided at the end portion of the surface 711 of the mounting board 701 on the same side as the pad electrodes 201 of the memory chips 200a. The pad electrode 710a is thus exposed on the same side as the pad electrodes 201 of the memory chips 200a. In the third configuration example, a pad electrode 710b is further provided at the end portion of the back surface 712 of the mounting board 701 on the opposite side to the pad electrode 710a, that is, at the end portion of the back surface 712 of the mounting board 701 on the same side as the pad electrodes 201 of the memory chips 200b. The pad electrode 710b is thus exposed on the same side as the pad electrodes 201 of the memory chips 200b.

In the third configuration example illustrated in FIG. 7, the pad electrode 710a and the pad electrodes 201 which are exposed on the same side, that is, the pad electrode 710a on the surface 711 of the mounting board 701 and the pad electrodes 201 of the memory chips 200a are electrically connected by a bonding wire 750. The pad electrode 710b and the pad electrodes 201 which are exposed on the same side, that is, the pad electrode 710b on the back surface 712 of the mounting board 701 and the pad electrodes 201 of the memory chips 200b are electrically connected by the bonding wire 750.

In the same manner as the first and second configuration examples described above, the third configuration example of the semiconductor device illustrated in FIG. 7 is mounted on the surface of a package board (not illustrated) including an external terminal for connecting to an external device, and is thereafter sealed with a resin or the like so as to be packaged as a single semiconductor device (for example, the memory 100 exemplified in FIG. 1). On the surface of the package board (not illustrated), electrodes are provided to be connected respectively to the pad electrodes 710a and 710b on the mounting board 701 through a bonding wire or the like.

In the third configuration example illustrated in FIG. 7, the single mounting board 701 is interposed between the two sets 400. In the embodiment, it is also allowable that the single mounting board 701 is interposed between three or more sets 400. In this case, it is permissible that the number of sets 400 to be mounted on the surface 711 of the mounting board 701 does not correspond with the number of sets 400 to be mounted on the back surface 712 of the mounting board 701.

### Fourth Configuration Example

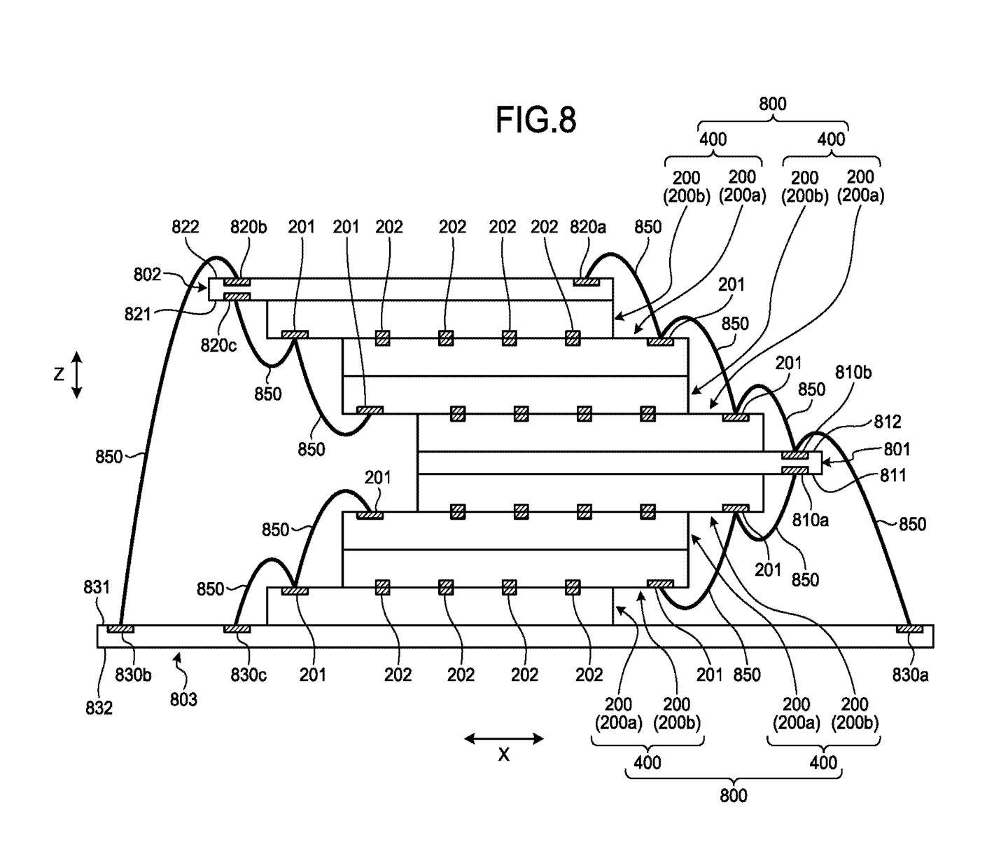

FIG. 8 is an exemplary and schematic diagram illustrating a fourth configuration example of the semiconductor device according to the embodiment. In the fourth configuration example illustrated in FIG. 8, a plurality (four) of sets 400 are stacked on one another into a V-shape (a dogleg shape) differently from the first to third configuration examples described above in which a plurality (two) of sets 400 are stacked in a stepwise manner.

In the fourth configuration example illustrated in FIG. 8, two structures 800 are provided, each of which is formed of two sets 400 stacked in a stepwise manner in the same manner as the aforementioned first to third configuration examples. The two structures 800 are located in such a manner that the pad electrodes 201 of the respective memory chips 200a in the lower structure 800 in the diagram are opposed to the pad electrodes 201 of the respective memory chips 200b in the upper structure 800 in the diagram. Due to this location, a stepwise structure configured by the lower structure 800 in the diagram and a stepwise structure configured by the upper structure 800 in the diagram are oriented symmetrically to each other relative to a mounting board 801. Thus, the structure is constructed in which the four sets 400 are stacked on one another into a V-shape (a dogleg shape).

In the fourth configuration example illustrated in FIG. 8, the mounting board 801 including a surface 811 and a back surface 812 is interposed between the two structures 800. The upper surface (the back surface 212 illustrated in FIGS. 3 and 4) of the memory chip 200b located at the uppermost position in the lower structure 800 in the diagram is bonded to the lower surface (the surface 811) of the mounting board 801. The lower surface (the back surface 212 illustrated in FIGS. 3 and 4) of the memory chip 200a located at the lowermost position in the upper structure 800 in the diagram is bonded to the upper surface (the back surface 812) of the mounting board 801.

Further, in the fourth configuration example illustrated in FIG. 8, the mounting board 801 is interposed between the two structures 800, and these two structures 800 are interposed between a mounting board 802 including a surface 821 and a back surface 822 and a mounting board 803 including a surface 831 and a back surface 832. The upper surface (the back surface 212 illustrated in FIGS. 3 and 4) of the memory chip 200b located at the uppermost position in the upper structure 800 in the diagram is bonded to the lower surface (the surface 821) of the mounting board 802. The lower surface (the back surface 212 illustrated in FIGS. 3 and 4) of the memory chip 200a located at the lowermost position in the lower structure 800 in the diagram is bonded to the upper surface (the back surface 831) of the mounting board 803.

In the fourth configuration example illustrated in FIG. 8, the mounting board 803 is formed larger in width in the X-direction than the mounting boards 801 and 802. That is, the mounting board 803 includes a section protruding in the X-direction relative to the mounting boards 801 and 802 in a state that the aforementioned structures are mounted on the surface 831. On this protruding section, pad electrodes 830a and 830b are provided which are described later.

In the fourth configuration example illustrated in FIG. 8, a pad electrode 810a is provided at the end portion of the surface 811 of the mounting board 801 on the same side as the pad electrodes 201 of the memory chips 200b in the lower structure 800 in the diagram. This pad electrode 810a is exposed on the same side as the pad electrodes 201 of the memory chips 200b in the lower structure 800 in the diagram. The pad electrode 810a is electrically connected to the pad electrodes 201 of the memory chips 200b in the lower structure 800 in the diagram by a bonding wire 850.

In the fourth configuration example illustrated in FIG. 8, a pad electrode 810b is further provided at the end portion of the back surface 812 of the mounting board 801 on the same side as the pad electrodes 201 of the memory chips 200a in the upper structure 800 in the diagram. This pad electrode 810b is exposed on the same side as the pad electrodes 201 of the memory chips 200a in the upper structure 800 in the diagram. Herein, a pad electrode 820a is provided at the end portion of the back surface 822 of the mounting board 802 on the same side as the pad electrode 810b, and a pad electrode 830a is provided at the end portion of the surface 831 of the mounting board 803 on the same side as the pad electrode 810b. The pad electrode 810b on the mounting board 801, the pad electrodes 201 of the memory chips 200a in the upper structure 800 in the diagram, the pad electrode 820a on the mounting board 802, and the pad electrode 830a on the mounting board 803 are electrically connected to one another by the bonding wire 850.

In the fourth configuration example illustrated in FIG. 8, a pad electrode 820b is provided at the end portion of the back surface 822 of the mounting board 802 on the opposite side to the pad electrode 820a. A pad electrode 830b is provided at the end portion of the surface 831 of the mounting board 803 on the opposite side to the pad electrode 830a. The pad electrode 820b on the mounting board 802 is electrically connected to the pad electrode 830b on the mounting board 803 by the bonding wire 850.

In the fourth configuration example illustrated in FIG. 8, a pad electrode 820c is further provided at the end portion of the surface 821 of the mounting board 802 on the same side as the pad electrodes 201 of the memory chips 200b in the upper structure 800 in the diagram. This pad electrode 820c is thus exposed on the same side as the pad electrodes 201 of the memory chips 200b in the upper structure 800 in the diagram. The pad electrode 820c is electrically connected to the pad electrodes 201 of the memory chips 200b in the upper structure 800 in the diagram by the bonding wire 850.

In the fourth configuration example illustrated in FIG. 8, a pad electrode 830c is further provided at the inner position on the surface of the mounting board 803 relative to the pad electrode 830b near the pad electrode 201 of the memory chip 200a located at the lowermost position in the lower structure 800 in the diagram. This pad electrode 830c is exposed on the same side as the pad electrodes 201 of the memory chips 200a in the lower structure 800 in the diagram. The pad electrode 830c is electrically connected to the pad electrodes 201 of the memory chips 200a in the lower structure 800 in the diagram by the bonding wire 850.

In the same manner as the first to third configuration examples described above, the fourth configuration example of the semiconductor device illustrated in FIG. 8 is mounted on the surface of a package board (not illustrated) including an external terminal for connecting to an external device, and is thereafter sealed with a resin or the like so as to be packaged as a single semiconductor device (for example, the memory 100 exemplified in FIG. 1). On the surface of the package board (not illustrated), electrodes are provided to be connected respectively to the electrodes 810a, 810b, 820a to 820c, and 830a to 830c on the mounting boards 801 to 803 through a bonding wire or the like.

In the fourth configuration example illustrated in FIG. 8, the four sets 400 are stacked on one another into a V-shape. In the embodiment, it is also allowable that three sets 400 or less, or five or more sets 400 are stacked on one another into a V-shape. In the fourth configuration example illustrated in FIG. 8, there is a V-shaped section at only a single location (where the mounting board 801 is provided). However, it is allowable in the embodiment that there are V-shaped sections at a plurality of locations.

As described above, the semiconductor device according to the embodiment includes a pair of memory chips 200 (200a and 200b), each of which includes the surface 211. The pad electrodes 201 are provided in the region R1 positioned at the end portion of the surface 211. The region R2 of the surface 211 of the memory chip 200a, other than the region R1, is bonded to the region R2 of the surface 211 of the memory chip 200b, other than the region R1 in a state of being opposed to each other, such that the pad electrode 201 of the memory chip 200a and the pad electrode 201 of the memory chip 201b are exposed in opposite directions to each other. In the region R2, the bump electrodes 202 which are electrically connected to the pad electrodes 201 are provided. The respective regions R2 of the memory chips 200a and 200b are bonded to each other in a state that the bump electrodes 202 of the memory chip 200a and the corresponding bump electrodes 202 of the memory chip 200b are electrically connected to each other. Due to this bonding, a semiconductor device with a more advantageous and novel configuration can be obtained. For example, the semiconductor device can reduce the wiring resistance, and reduce the influence of noise and the like.

<Modification>

In the embodiment described above, a configuration has been exemplified in which a pair of memory chips, which are configured as identical components, is bonded in a state of being opposed to each other. However, in a modification of the embodiment, it is also possible that two memory chips, which have different shapes and structures from each other, are bonded in a state of being opposed to each other.

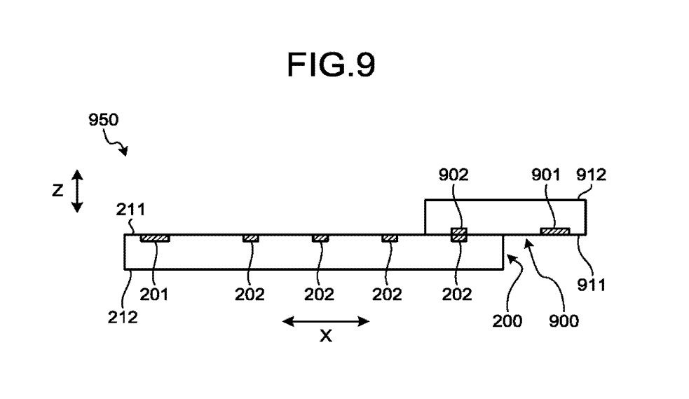

FIG. 9 is an exemplary and schematic diagram illustrating a set 950 of a memory chip 900 and the memory chip 200 according to the modification of the embodiment. In the modification illustrated in FIG. 9, a single set 950 is formed of a combination of the memory chip 200 that is identical to the above-described embodiment and the memory chip 900 that is sized smaller than this memory chip 200.

In the modification illustrated in FIG. 9, the upper memory chip 900 in the diagram includes a surface 911 and a back surface 912. On the surface 911, a pad electrode 901 that receives power supply, a control signal, and the like from external devices are provided, and a bump electrode 902 that is connected to the pad electrode 901 through a wire (not illustrated) provided in the memory chip 900 are provided.

In the modification illustrated in FIG. 9, a region of the surface 911 of the memory chip 900, where the bump electrode 902 is provided, is bonded to a region of the surface 211 of the memory chip 200, where the bump electrode 202 is provided at a position most distanced from the pad electrode 201, in a state that these regions are opposed to each other, such that the pad electrode 901 on the surface 911 of the memory chip 900, the pad electrode 201 on the surface 211 of the memory chip 200, and three bump electrodes 202 which are closer to this pad electrode 201 are exposed.

In the modification illustrated in FIG. 9, the bump electrode 902 on the surface 911 of the memory chip 900 and the bump electrode 202 at the position most distanced from the pad electrode 201 on the surface 211 of the memory chip 200 are brought into alignment with each other and are electrically connected to each other. Therefore, in a case where the bump electrode 902 on the surface 911 of the memory chip 900 is configured as the power conductor, the bump electrode 202 at the position most distanced from the pad electrode 201 on the surface 211 of the memory chip 200 is also configured as the power conductor in order to ensure electrical matching. Similarly, in a case where the bump electrode 902 on the surface 911 of the memory chip 900 is configured as the data conductor, the bump electrode 202 at the position most distanced from the pad electrode 201 on the surface 211 of the memory chip 200 is also configured as the data conductor.

In the same manner as the first to fourth configuration examples described above, the modification of the semiconductor device illustrated in FIG. 9 is mounted on one or a plurality of mounting boards (not illustrated), then mounted on the surface of a package board (not illustrated) including an external terminal for connecting to an external device, and thereafter sealed with a resin or the like so as to be packaged as a single semiconductor device (for example, the memory 100 exemplified in FIG. 1). On the mounting board (not illustrated), electrodes are provided to be connected respectively to the pad electrode 201 of the memory chip 200 and the pad electrode 901 of the memory chip 900 through a bonding wire or the like. On the surface of the package board (not illustrated), electrodes are provided to be connected respectively to the electrodes on the mounting board through a bonding wire or the like.

Further, in a possible configuration according to another modification, the memory chip 900 illustrated in FIG. 9 is bonded to another memory chip 900 in a state that the bump electrodes 902 are aligned with and opposed to each other such that the pad electrodes 901 are exposed in opposite directions to each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first chip including a first surface including a first region at an end, the first region in which a first electrode is provided; and
a second chip including a second surface including a second region at an end, the second region in which a second electrode is provided, wherein
a third region of the first surface of the first chip, other than the first region, and a fourth region of the second surface of the second chip, other than the second region, are bonded in a state that the third region and the fourth region are at least partially opposed to each other, such that the first electrode of the first chip and the second electrode of the second chip are exposed in opposite directions to each other.

2. The semiconductor device according to claim 1, wherein
a first conductor electrically connected to the first electrode is provided in the third region,
a second conductor electrically connected to the second electrode is provided in the fourth region, and
the third region and the fourth region are at least partially bonded in a state that the first conductor and the second conductor are electrically connected.

3. The semiconductor device according to claim 2, wherein
the third region and the fourth region are at least partially bonded in a state that the first conductor and the second conductor are brought into alignment with each other.

4. The semiconductor device according to claim 3, wherein
the first conductor and the second conductor each include a power conductor as a part of a power line and a data conductor as a part of a data bus, and
the third region and the fourth region are at least partially bonded in a state that the power conductor of the first conductor and the power conductor of the second conductor are brought into alignment with each other and the data conductor of the first conductor and the data conductor of the second conductor are brought into alignment with each other.

5. The semiconductor device according to claim 1, comprising a plurality of sets of the first chip and the second chip bonded to each other, wherein
the sets are stacked on one another such that a third surface of the first chip on an opposite side to the first surface and a fourth surface of the second chip on an opposite side to the second surface are opposed to each other, and
the first electrodes of the first chips in the sets are electrically connected to each other and the second electrodes of the second chips in the sets are electrically connected to each other.

6. The semiconductor device according to claim 5, further comprising:
a first mounting board including a first mounting surface on which a third electrode is provided at an end; and
a second mounting board including a second mounting surface on which a fourth electrode is provided at an end, wherein
the sets are interposed between the first mounting surface of the first mounting board and the second mounting surface of the second mounting board such that the third electrode is exposed on a same side as the first electrode and the fourth electrode is exposed on a same side as the second electrode, and
the first electrode and the third electrode are electrically connected and the second electrode and the fourth electrode are electrically connected.

7. The semiconductor device according to claim 5, further comprising a third mounting board including a third mounting surface on which a fifth electrode is provided at an end and including a back surface of the third mounting surface on which a sixth electrode is provided at an end opposite to the fifth electrode, wherein
the sets are stacked on the third mounting board such that the fifth electrode is exposed on a side of one of the first electrode and the second electrode, and
the one of the first electrode and the second electrode and the fifth electrode are electrically connected, and the other one of the first electrode and the second electrode and the sixth electrode are electrically connected.

8. The semiconductor device according to claim 5, further comprising a fourth mounting board, the fourth mounting board including a fourth mounting surface on which a seventh electrode is provided at an end and including a fifth mounting surface on which an eighth electrode is provided at an end opposite to the seventh electrode, the fifth mounting surface being positioned on an opposite side to the fourth mounting surface, wherein
the fourth mounting board is interposed between the sets such that the seventh electrode is exposed on a side of the first electrode and the eighth electrode is exposed on a side of the second electrode, and
the first electrode and the seventh electrode are electrically connected and the second electrode and the eighth electrode are electrically connected.

9. The semiconductor device according to claim 1, wherein
the first chip and the second chip are configured as identical components.

10. A manufacturing method of a semiconductor device, the semiconductor device including a first chip and a second chip, the first chip including a first surface including a first region at an end, the first region in which a first electrode is provided, the second chip including a second surface including a second region at an end, the second region in which a second electrode is provided, the manufacturing method comprising
bonding a third region of the first surface of the first chip, other than the first region, and a fourth region of the second surface of the second chip, other than the second region, in a state that the third region and the fourth region are at least partially opposed to each other, such that the first electrode of the first chip and the second electrode of the second chip are exposed in opposite directions to each other.

11. The manufacturing method of the semiconductor device according to claim 10, comprising at least partially bonding the third region and the fourth region in a state that a first conductor and a second conductor are electrically connected, the first conductor being provided in the third region and electrically connected to the first electrode, the second conductor being provided in the fourth region and electrically connected to the second electrode.

12. The manufacturing method of the semiconductor device according to claim 11, comprising at least partially bonding the third region and the fourth region in a state that the first conductor and the second conductor are brought into alignment with each other.

13. The manufacturing method of the semiconductor device according to claim 12, comprising
when the first conductor and the second conductor each include a power conductor as a part of a power line and a data conductor as a part of a data bus, at least partially bonding the third region and the fourth region in a state that the power conductor of the first conductor and the power conductor of the second conductor are brought into alignment with each other and the data conductor of the first conductor and the data conductor of the second conductor are brought into alignment with each other.

14. The manufacturing method of the semiconductor device according to claim 10, comprising:
preparing a plurality of sets of the first chip and the second chip bonded to each other;
stacking the sets on one another such that a third surface of the first chip on an opposite side to the first surface and a fourth surface of the second chip on an opposite side to the second surface are opposed to each other; and
electrically connecting the first electrodes of the first chips in the sets to each other and electrically connecting the second electrodes of the second chips in the sets to each other.

15. The manufacturing method of the semiconductor device according to claim 14, comprising:
preparing a first mounting board and a second mounting board, the first mounting board including a first mounting surface on which a third electrode is provided at an end, the second mounting board including a second mounting surface on which a fourth electrode is provided at an end;
interposing the sets between the first mounting surface of the first mounting board and the second mounting surface of the second mounting board such that the third electrode is exposed on a same side as the first electrode and the fourth electrode is exposed on a same side as the second electrode; and
electrically connecting the first electrode and the third electrode and electrically connecting the second electrode and the fourth electrode.

16. The manufacturing method of the semiconductor device according to claim 14, comprising:
preparing a third mounting board including a third mounting surface on which a fifth electrode is provided at an end and including a back surface of the third mounting surface on which a sixth electrode is provided at an end opposite to the fifth electrode;
stacking the sets on the third mounting board such that the fifth electrode is exposed on a side of one of the first electrode and the second electrode; and
electrically connecting the one of the first electrode and the second electrode and the fifth electrode and electrically connecting the other one of the first electrode and the second electrode and the sixth electrode.

17. The manufacturing method of the semiconductor device according to claim 14, comprising:
preparing a fourth mounting board, the fourth mounting board including a fourth mounting surface on which a seventh electrode is provided at an end and including a fifth mounting surface on which an eighth electrode is provided at an end opposite to the seventh electrode, the fifth mounting surface being positioned on an opposite side to the fourth mounting surface;
interposing the fourth mounting board between the sets such that the seventh electrode is exposed on a side of the first electrode and the eighth electrode is exposed on a side of the second electrode; and
electrically connecting the first electrode and the seventh electrode and electrically connecting the second electrode and the eighth electrode.

18. The manufacturing method of the semiconductor device according to claim 10, comprising using the first chip and the second chip configured as identical components.
